(19) United States
(12) Patent Application Publication
(10) Pub. No.: US 2012/0107587 A1
(43) Pub. Date: May 3, 2012

(54) SUBSTRATE WHICH IS EQUIPPED WITH A STACK HAVING THERMAL PROPERTIES

(75) Inventors: ESTELLE MARTIN, Paris (FR); Eric Mattmann, Paris (FR); Pascal Reutler, Paris (FR); Eric PetitJean, Les Lilas (FR); Jonathan Schneider, Torgau (DE)

(73) Assignee: SAINT-GOBAIN GLASS FRANCE, Courbevoie (FR)

(21) Appl. No.: 13/347,912

(22) Filed: Jan. 11, 2012

Related U.S. Application Data
(63) Continuation of application No. 12/092,640, filed on Aug. 27, 2008, now abandoned.

(30) Foreign Application Priority Data
Nov. 8, 2005 (FR) 0553386

(51) Int. Cl. B32B 7/02; C23C 14/35; C23C 14/08; B32B 15/00; B32B 3/00

(52) U.S. Cl. 428/216; 428/434; 428/336; 204/192.27

(57) ABSTRACT

The invention relates to a substrate (10), especially a transparent glass substrate, provided with a thin-film multilayer coating comprising an alternation of n functional layers (40) having reflection properties in the infrared and/or in solar radiation, especially metallic functional layers based on silver or on metal alloy containing silver, and (n+1) dielectric films (20, 60), where n≧1, said films being composed of a layer or a plurality of layers (22, 24, 62, 64), at least one of which is made of a dielectric material, so that each functional layer (40) is placed between at least two dielectric films (20, 60), characterized in that at least one functional layer (40) includes a blocker film (30, 50) consisting of at least one interface layer (32, 52) immediately in contact with said functional layer, this interface layer being based on titanium oxide TiOₓ.

The invention relates to transparent substrates, especially those made of a rigid mineral material such as glass, said substrates being coated with a thin-film multilayer coating comprising at least one functional layer of metallic type which can act on solar radiation and/or infrared radiation of long wavelength.

The invention relates more particularly to the use of such substrates for manufacturing thermal insulation and/or solar protection glazing units. These glazing units are intended for equipping both buildings and vehicles, especially with a view to reducing air-conditioning load and/or reducing excessive overheating (glazing called “solar control” glazing) and/or reducing the amount of energy dissipated to the outside (glazing called “low-E” or “low-emissivity” glazing) brought about by the ever growing use of glazed surfaces in buildings and vehicle passenger compartments.

One type of multilayer coating known for giving substrates such properties consists of at least one metallic functional layer, such as a silver layer, which is placed between two films made of dielectric material of the metal oxide or nitride type. This multilayer coating is generally obtained by a succession of deposition operations carried out using a vacuum technique, such as sputtering, possibly magnetically enhanced or magnetron sputtering. Two very thin films may also be provided, these being placed on each side of the silver layer—the subjacent film as a tie, nucleation and/or protection layer, for protection during a possible heat treatment subsequent to the deposition, and the superjacent film as a “sacrificial” or protection layer so as to prevent the silver from being impaired if the oxide layer that surmounts it is deposited by sputtering in the presence of oxygen and/or if the multilayer coating undergoes a heat treatment subsequent to the deposition.

Thus, multilayer coatings of this type, with one or two silver-based metallic functional layers, are known from European patents EP-0 611 213, EP-0 678 484 and EP-0 638 528.

Currently, there is an increasing demand for this low-emissivity or solar-protection glazing to also have characteristics inherent in the substrates themselves, especially esthetic characteristics (for the glazing to be able to be curved), mechanical properties (to be stronger) or safety characteristics (to cause no injury by broken fragments). This requires the glass substrates to undergo heat treatments known per se, of the bending, annealing or toughening type, and/or treatments associated with the production of laminated glazing.

The multilayer coating then has to be adapted in order to preserve the integrity of the functional layers of the silver-layer type, especially to prevent their impairment. A first solution consists in significantly increasing the thickness of the abovementioned thin metal layers that surround the functional layers: thus, measures are taken to ensure that any oxygen liable to diffuse from the ambient atmosphere and/or to migrate from the glass substrate at high temperature is “captured” by these metal layers, which oxidizes them, without it reaching the functional layer(s).

These layers are sometimes called “blocking layers” or “blocker layers”.

One may especially refer to patent application EP-A-0 506 507 for the description of a “toughenable” multilayer coating having a silver layer placed between a tin layer and a nickel-chromium layer. However, it is clear that the substrate coated before the heat treatment was considered merely as a “semifinished” product—the optical characteristics frequently rendered it unusable as it was. It was therefore necessary to develop and manufacture, in parallel, two types of multilayer coating, one for noncurved/nontoughened glazing and the other for glazing intended to be toughened or curved, which may be complicated, especially in terms of stock management and production.

An improvement proposed in patent EP-0 718 250 has allowed this constraint to be overcome, the teaching of that document consisting in devising a thin-film multilayer coating such that its optical and thermal properties remain virtually unchanged, whether or not the substrate once coated with the multilayer coating undergoes a heat treatment. Such a result is achieved by combining two characteristics:
on the one hand, a layer made of a material capable of acting as a barrier to high-temperature oxygen diffusion is provided on top of the functional layer(s), which material itself does not undergo, at high temperature, a chemical or structural change that would modify its optical properties. Thus, the material may be silicon nitride Si₃N₄ or aluminum nitride AlN; and
on the other hand, the functional layer(s) is (are) directly in contact with the subjacent dielectric, especially zinc oxide ZnO, coating.

A single blocker layer (or monolayer blocker coating) is also, preferably, provided on the functional layer or layers. This blocker layer is based on a metal chosen from niobium Nb, tantalum Ta, titanium Ti, chromium Cr or nickel Ni or from an alloy based on at least two of these metals, especially a niobium/tantalum (Nb/Ta) alloy, a niobium/chromium (Nb/Cr) alloy or a tantalum/chromium (Ta/Cr) alloy or a nickel/chromium (Ni/Cr) alloy.

Although this solution does actually allow the substrate after heat treatment to preserve a T_{L} level and an appearance in external reflection that are quite constant, it is still capable of improvement.

Moreover, the search for a better resistivity of the multilayer coating, that is to say a lower resistivity, is a constant search.

The state of the functional layer has been the subject of many studies as it is, of course, a major factor in the resistivity of the functional layer.

The inventors have chosen to explore another approach for improving the resistivity, namely the nature of the interface between the functional layer and the immediately adjacent blocker layer.

The prior art teaches, from international patent application WO 2004/058660, a solution whereby the overblocker film is an NICrOₓ monolayer, possibly having an oxidation gradient. According to that document, the part of the blocker layer in contact with the functional layer is less oxidized than the part of this layer further away from the functional layer using a particular deposition atmosphere.

The object of the invention is therefore to remedy the drawbacks of the prior art, by developing a novel type of multilayer coating comprising one or more functional layers of the type of those described above, which multilayer coating can undergo high-temperature heat treatments of the bending, toughening or annealing type while preserving its optical quality and its mechanical integrity and having an improved resistivity.

The invention constitutes in particular a suitable solution to the usual problems of the intended application and consists in developing a compromise between the thermal properties and the optical qualities of the thin-film multilayer coating.

In fact, improving the resistivity, the reflection properties in the infrared and the emissivity of a multilayer coating usually causes a deterioration in the light transmission and thin colors reflection of this multilayer coating.

Thus, the subject of the invention, in its broadest acceptance, is a substrate, especially a transparent glass substrate, provided with a thin-film multilayer coating comprising an alternation of n functional layers having reflection properties in the infrared and/or in solar radiation, especially metallic functional layers based on silver or on a metal alloy containing silver, and (n+1) dielectric films, where n≧1, (n of course being an integer), said films being composed of a layer or a plurality of layers, including at least one made of a dielectric material, so that each functional layer is placed between at least two dielectric films, characterized in that at least one functional layer includes a blocker film consisting of at least one interface layer immediately in contact with said functional layer, this interface layer being based on titanium oxide TiOₓ.

The invention thus consists in providing blocker film for the functional layer with at least one layer, this blocker film being located beneath the functional layer (“underblocker” film) and/or on the functional layer (“overblocker” film).

The inventors have thus taken into consideration the fact that the state of oxidation, and even the degree of oxidation, of the layer immediately in contact with the functional layer could have a major influence on the resistivity of the layer.

The invention does not only apply to multilayer coatings comprising a single “functional” layer placed between two films. It also applies to multilayer coatings having a plurality of functional layers, especially two functional layers alternating with three films, or three functional layers alternating with four films, or even four functional layers alternating with five films.

In the case of a multilayer coating having multiple functional layers, at least one functional layer, and preferably each functional layer, is provided with an underblocker film and/or with an overblocker film according to the invention, that is to say a blocker film comprising at least two separate layers.

In one particular embodiment, the interface layer is partially oxidized. It is therefore not deposited in stoichiometric form but in nonstoichiometric form and preferably substoichiometric form, of the MOₓ type, where M represents the material and x is a number different than the stoichiometry of the titanium oxide TiO₂, that is to say different than 2 and preferably less than 2, in particular between 0.75 times and 0.99 times the normal stoichiometry of the oxide. TiOₓ may in particular be such that 1.5≦x≦1.98 or 1.5<x<1.7 or even 1.7≦x≦1.95.

The interface layer preferably has a geometric thickness of less than 5 nm and preferably between 0.5 and 2 nm, and the blocker film therefore preferably has a geometric thickness of less than 5 nm and preferably between 0.5 and 2 nm. This thickness may however be greater than and in particular double the thickness of the interface layer if another layer is provided in the blocker film.

The effect underlying the invention may be confirmed by local chemical analysis carried out in contact with the functional layer and with the blocker film using transmission electron microscopy (TEM) combined with electron energy loss spectroscopy (EELS).

The interface layer according to the invention may include one or more other chemical elements chosen from at least one of the following materials Ti, V, Mn, Co, Cu, Zn, Zr, Hf, Al, Nb, Ni, Cr, Mo, Ta, or from an alloy based on at least one of these materials.

Moreover, the blocker film according to the invention may further include one or more other layers, further away from the functional layer than the TiOₓ interface layer, such as for example a metallic layer, and in particular a titanium metal Ti layer.

The glazing according to the invention incorporates at least the substrate carrying the multilayer coating according to the invention, optionally combined with at least one other substrate. Each substrate may be clear or tinted. At least one of the substrates may especially be made of bulk-tinted glass. The choice of coloration type will depend on the level of light transmission and/or on the colorimetric appearance that is/are desired for the glazing once its manufacture has been completed.

Thus, for glazing intended to equip vehicles, standards impose that windshields have a light transmission T_{L} of about 75% according to some standards or 70% according to other standards, such a level of transmission not being required for the side windows or a sunroof for example. The tinted glass that can be used is for example that, for a thickness of 4 mm, having a T_{L} of 65% to 95%, an energy transmission T_{E} of 40% to 80%, a dominant wavelength in transmission of 470 nm to 525 nm, associated with a transmission purity of 0.4% to 6% under illuminant D₆₅, which may “result”, in the (L,a*,b*) colorimetry system, in a* and b* values in transmission of between −9 and 0 and between −8 and +2, respectively.

For glazing intended to equip buildings, it preferably has a light transmission T_{L} of at least 75% or higher in the case of “low-E” applications, and a light transmission T_{L} of at least 40% or higher for “solar control” applications.

The glazing according to the invention may have a laminated structure, especially one combining at least two rigid substrates of the glass type with at least one sheet of thermoplastic polymer, so as to have a structure of the type: glass/thin-film multilayer coating/sheet(s)/glass. The polymer may especially be based on polyvinyl butyral (PVB), ethylene/vinyl acetate (EVA), polyethylene terephthalate (PET) or polyvinyl chloride (PVC).

The glazing may also have what is called an asymmetric laminated glazing structure, which combines a rigid substrate of the glass type with at least one sheet of polymer of the polyurethane type having energy-absorbing properties, optionally combined with another layer of polymers having “self-healing” properties. For further details about this type of glazing, the reader may refer especially to patents EP-0 132 198, EP-0 131 523 and EP-0 389 354. The glazing may therefore have a structure of the type: glass/thin-film multilayer coating/polymer sheet(s).

In a laminated structure, the substrate carrying the multilayer coating is preferably in contact with a sheet of polymer.

The glazing according to the invention is capable of undergoing a heat treatment without damaging the thin-film multilayer coating. The glazing is therefore possibly curved and/or toughened.

The glazing may be curved and/or toughened when consisting of a single substrate, that provided with the multilayer coating. Such glazing is then referred to as “monolithic” glazing. When it is curved, especially for the purpose of making windows for vehicles, the thin-film multilayer coating preferably is on an at least partly nonplanar face.

The glazing may also be a multiple glazing unit, especially a double-glazing unit, at least the substrate carrying the multilayer coating being curved and/or toughened. It is preferable in a multiple glazing configuration for the multilayer coating to be placed so as to face the intermediate gas-filled space.

When the glazing is monolithic or is in the form of multiple glazing of the double-glazing or laminated glazing type, at least the substrate carrying the multilayer coating may be made of curved or toughened glass, it being possible for the substrate to be curved or toughened before or after the multilayer coating has been deposited.

The invention also relates to a process for manufacturing substrates according to the invention, which consists in depositing the thin-film multilayer coating on its substrate, in particular made of glass, by a vacuum technique of the sputtering, optionally magnetron sputtering, type. It is then possible to carry out a bending, toughening or annealing heat treatment on the coated substrate without degrading its optical and/or mechanical quality.

However, it is not excluded for the first layer or first layers to be able to be deposited by another technique, for example by a thermal decomposition technique of the pyrolysis or CVD type.

The interface layer is deposited using a ceramic target in a nonoxidizing atmosphere (i.e. without intentional introduction of oxygen) preferably consisting of noble gas(es) (He, Ne, Xe, Ar, or Kr).

The details and advantageous features of the invention will emerge from the following nonlimiting examples illustrated by means of the figures thereto:

FIG. 1 illustrates a multilayer coating having a single functional layer, the functional layer of which is coated with a blocker film according to the invention;

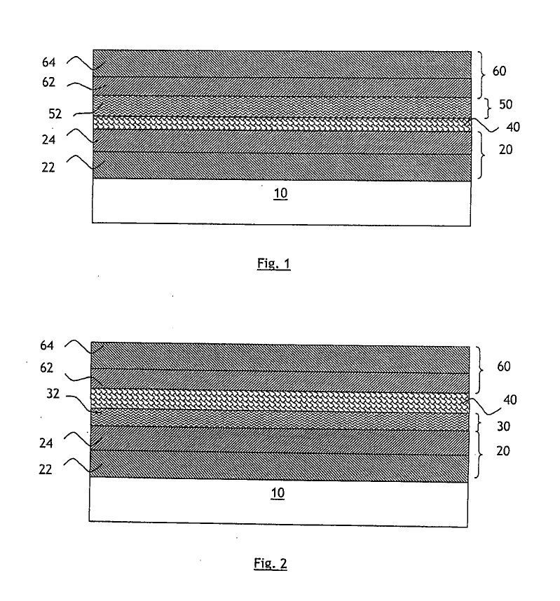

FIG. 2 illustrates a multilayer coating having a single functional layer, the functional layer of which is deposited on a blocker film according to the invention;

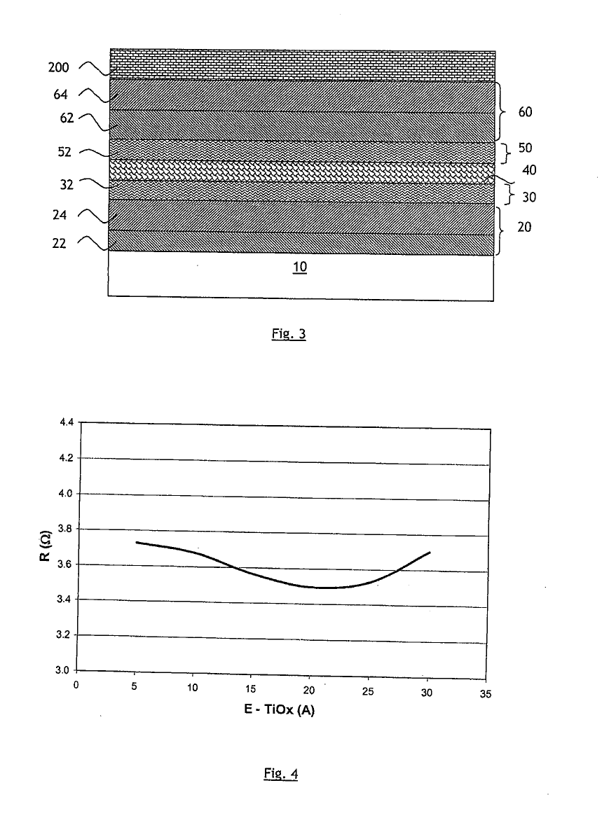

FIG. 3 illustrates a multilayer coating that includes a single functional layer, the functional layer being deposited on an overblocker film according to the invention and beneath an underblocker film according to the invention;

FIG. 4 illustrates the resistivity in ohms per square of a multilayer coating according to example 5 as a function of the thickness in Angstroms of the interface layer according to the invention;

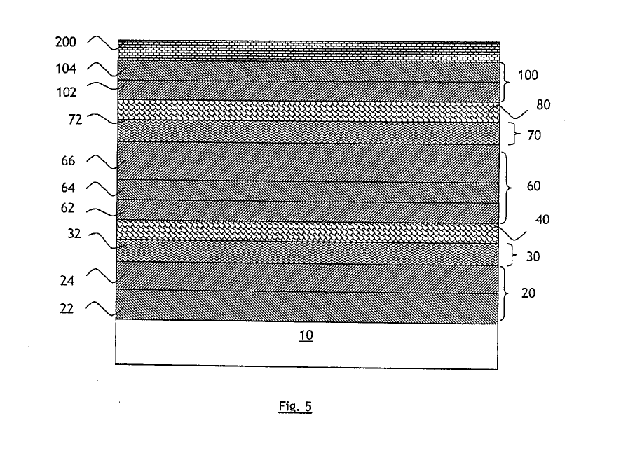

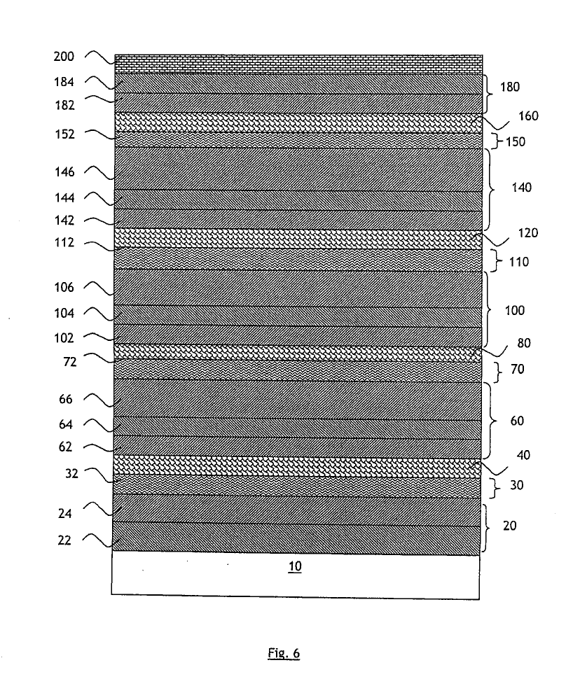

FIG. 5 illustrates a multilayer coating that includes two functional layers, each functional layer being deposited on an underblocker film according to the invention; and

FIG. 6 illustrates a multilayer coating that includes four functional layers, each functional layer being deposited on an underblocker film according to the invention.

The thicknesses of the various layers of the multilayer coatings in the figures have not been drawn in proportion so as to make them easier to read.

FIGS. 1 and 2 illustrate diagrams of multilayer coatings that include a single functional layer, when the functional layer is provided with an overblocker film and when the functional layer is provided with an underblocker film, respectively.

In the examples 1 to 5 and 11 to 13 that follow, the multilayer coating is deposited on the substrate 10, which is a substrate made of clear soda-lime-silica glass 2.1 mm in thickness. The multilayer coating includes a single silver-based functional layer 40.

Beneath the functional layer 40 is a dielectric film 20 consisting of a plurality of superposed dielectric-based layers 22, (23), 24 and on the functional layer 40 is a dielectric film 60 consisting of a plurality of superposed dielectric-based layers 62, 64.

In examples 1 to 3 and 11 to 13:
the layers 22 are based on Si₃N₄ and have a physical thickness of 20 nm;
the layers 24 are based on ZnO and have a physical thickness of 8 nm;
the layers 62 are based on ZnO and have a physical thickness of 8 nm;
the layers 64 are based on Si₃N₄ and have a physical thickness of 20 nm; and
the layers 40 are based on silver and have a physical thickness of 10 nm.

In the various examples 1 to 3 and 11 to 13, only the nature and the thickness of the blocker film change.

In the case of examples 1 and 11, which are counter-examples, the respective blocker film 50, 30 comprises a single respective metal layer, here made of titanium metal neither oxidized nor nitrided, this layer being deposited in a pure argon atmosphere.

In the case of examples 2 and 12, which are examples according to the invention, the respective blocker film 50, 30 comprises an interface layer, respectively 52, 32 made of an oxide, here substoichiometric titanium oxide TiOₓ with a thickness of 1 nm, deposited in a pure argon atmosphere using a ceramic cathode.

In the case of examples 3 and 13, which are examples according to the invention, the respective blocker film 50, 30 comprises a respective oxide interface layer 52, 32, here substoichiometric titanium oxide TiOₓ with a thickness of 2 nm, deposited in a pure argon atmosphere using a ceramic cathode.

In all these examples, the successive layers of the multilayer coating are deposited by magnetron sputtering, but any other deposition technique may be envisioned provided that the layers are deposited in a well-controlled manner with well-controlled thicknesses.

The deposition installation comprises at least one sputtering chamber provided with cathodes equipped with targets made of suitable materials, beneath which the substrate 1 passes in succession. These deposition conditions for each of the layers are the following:
the silver-based layers 40 are deposited using a silver target, under a pressure of 0.8 Pa in a pure argon atmosphere;
the ZnO-based layers 24 and 62 are deposited by reactive sputtering using a zinc target, under a pressure of 0.3 Pa and in an argon/oxygen atmosphere; and
the Si₃N₄-based layers 22 and 64 are deposited by reactive sputtering using an aluminum-doped silicon target, under a pressure of 0.8 Pa in an argon/nitrogen atmosphere.

The power densities and the run speeds of the substrate 10 are adjusted in a known manner in order to obtain the desired layer thicknesses.

For each of the examples, the resistance of each multilayer coating was measured, before a heat treatment (BHT) and after this heat treatment (AHT).

The heat treatment applied consists at each time in heating at 620° C. for 5 minutes followed by rapid cooling in the ambient air (at about 25° C.).

The results of the resistance measurements were converted into resistivities R in ohms per square and are given in the tables below.

TABLE 1
overblocker film 50

| | R_{BHT} (ohms/□) | R_{AHT} (ohms/□) |
|---|---|---|
| Ex. 1 | 8.3 | 4.8 |
| Ex. 2 | 5.1 | 4 |
| Ex. 3 | 5 | 4 |

In the case of the TiOₓ interface layer, comparison between the resistivity values before heat treatment of example 1 and the resistivity values before heat treatment of examples 2 and 3 clearly shows an improvement in the resistivity of examples 2 and 3, with resistivity values well below those of example 1.

The presence of the TiOₓ layer deposited on the silver-based metallic functional layer instead of the titanium metal layer therefore improves the resistivity before or without heat treatment.

Comparison between the resistivity values after heat treatment of example 1 and the resistivity values after heat treatment of examples 2 and 3 also clearly shows an improvement in the resistivity in the case of examples 2 and 3 with resistivity values below those obtained with example 1.

These results prove the strong influence of the state of oxidation at the interface with the silver-based functional metallic layer in the overblocker film.

Thus, in the case of the overblocker film, an oxidized state of the titanium at this interface with the silver-based layer improves the resistivity, whereas a metallic state is to the detriment of the resistivity.

To ensure that this is so, we then carried out the deposition in the same manner as that of example 3, except that the atmosphere for depositing the interface layer 52 made of TiOₓ was modified: from a nonoxidizing atmosphere, we went to a slightly oxidizing atmosphere with an oxygen flux of 1 sccm for an argon flux of 150 sccm.

We observed that, with only a very slightly oxidizing state, the resistivity of the multilayer coating was still much higher than in the case of example 1.

The fundamental mechanism for this reduction in resistivity at the interface with the silver is not completely understood. Possibly there is a chemical reaction and/or diffusion of oxygen.

Using electron energy loss spectroscopy (EELS), a profile through the blocker film was obtained from this counterexample of example 3. This experiment showed that near the functional layer the oxygen signal is detected for this counterexample.

TABLE 2
underblocker film 30

| | R_{BHT} | R_{AHT} | T_{L, BHT} | T_{L, AHT} |
|---|---|---|---|---|
| | (ohms/□) | (ohms/□) | (%) | (%) |
| Ex. 11 | 8 | 4.8 | 81.4 | 84.5 |
| Ex. 12 | 7.7 | 5 | | |
| Ex. 13 | 6.7 | 4.7 | 82.9 | 87.3 |

The case of the underblocker film is more complex than that of the overblocker, since this film influences the heteroepitaxy of the silver on the subjacent oxide layer, in this case based on zinc oxide.

Unlike the overblocker film, the underblocker film is not in general exposed to an oxygen-containing plasma atmosphere. This means that when the underblocker film is made of unoxidized and/or non-nitrided titanium metal, it will of course be neither oxidized nor nitrided at the interface with the silver-based functional layer.

Deposition of an oxide interface layer between the metallic blocker layer and the metallic functional layer is thus the only way of controlling the oxygen content at the interface between the underblocker film and the functional metallic layer.

In the case of the TiOₓ interface layer, comparison between the resistivity values before heat treatment of example 11 and the resistivity values before heat treatment of examples 12 and 13 clearly shows an improvement in the resistivity of examples 12 and 13, with resistivity values well below those of example 11.

The presence of the TiOₓ layer deposited instead of the titanium metal layer and beneath the silver-based metallic functional layer therefore improves the resistivity before or without heat treatment.

Comparison between the resistivity values after heat treatment of example 11 and the resistivity values after heat treatment of examples 12 and 13 does not show an improvement in the resistivity in the case of examples 12 and 13, with resistivity values similar to those obtained with example 11.

These results also prove the strong influence of the state of oxidation at the interface with the silver-based functional metallic layer in the underblocker film.

Thus, in the case of the underblocker film too, an oxidized state of the titanium at this interface with the silver-based layer improves the resistivity, whereas a metallic state is to the detriment of the resistivity.

Moreover, the presence of the TiOₓ interface layer 32 improves the light transmission, both before heat treatment and after this treatment.

Finally, the colorimetry measurements in reflection on the multilayer coating side have shown that, in the case of example 13, the a* and b* values in the Lab system remained within the preferred “color palette”, that is to say with a* values of around 0 and b* values of around −3.5, whereas in the case of example 11, the a* values were around 1.2 and the b* values were around −6.8.

The results of the mechanical resistance to the various tests usually carried out on thin-film multilayer coatings (Taber test, Erichsen brush test, etc.) are not very good, but these results are improved by the presence of a protective layer on the top of the multilayer coating.

In examples 4 and 5 according to the invention, a configuration similar to that of FIG. 1 was employed, with, in the following order, on the substrate:
an SnO₂-based layer 22;
a TiO₂-based intermediate layer 23 (not illustrated in FIG. 1);
a ZnO-based layer 24;
a silver-based functional metallic layer 40;
an interface layer 52 made of a substoichiometric titanium oxide TiOₓ, with a physical thickness of 2 nm;
a ZnO-based layer 62;
an Si₃N₄-based layer 64; and
a protection layer based on a tin zinc mixed oxide with a physical thickness of 3 nm.

In the case of examples 4 and 5, which are examples according to the invention, a respective blocker film 50 comprises an oxide interface layer 52, here substoichiometric titanium oxide TiOₓ, with a thickness of 2 nm, deposited in a pure argon atmosphere using a ceramic cathode.

The layers 24, 40, 52, 62 and 64 were deposited as previously.

The SnO₂-based layer 22 was deposited by reactive sputtering using a metallic tin target, under a pressure of 0.3 Pa and in an argon/oxygen atmosphere, and the TiO₂-based layer 23 was deposited by reactive sputtering using a metallic tin target under a pressure of 0.3 Pa and in an argon/oxygen atmosphere.

Table 3 below summarizes the physical thicknesses in nanometers of the layers of both examples 4 and 5 according to the invention and table 4 the essential characteristics of these examples.

TABLE 3

| Layer | Ex. 4 | Ex. 5 |
|---|---|---|
| 22 | 9 | 12 |
| 23 | 11 | 12 |
| 24 | 5 | 6 |
| 40 | 14 | 10.5 |
| 52 | 2 | 2 |
| 62 | 8 | 7 |
| 64 | 40 | 32 |

Moreover, a counterexample of example 5 was produced by depositing a multilayer coating identical to that of example 5 except that the layer 52 was not deposited in the form of titanium oxide with a thickness of 2 nm but in the form of metallic titanium with a thickness of 0.5 nm, deposited in an inert (argon) atmosphere.

TABLE 4

| | R_{BHT} | T_{L, BHT} | | |
|---|---|---|---|---|
| | (ohms/□) | (%) | a* | b* |
| Ex. 4 | 2 | 78.5 | 1 | −5 |
| Ex. 5 | 3.5 | 88 | 1.5 | −6.5 |
| Counter- | 3.8 | 88 | 2.5 | −6 |
| ex. 5 | | | | |

(the colors are those observed in reflection on the multilayer side)

The characteristics of this counterexample clearly show the positive effect of the interface layer according to the invention on the resistivity of the multilayer coating, and also on the colorimetry.

In order for this effect to be even better understood, a series of trials was carried out on the basis of example 5, by varying the thickness of the interface layer between 0.5 and 3 nanometers.

The resistivity obtained is given in FIG. 4. This figure thus shows that the resistivity obtained is quite constant, irrespective of the thickness of the interface layer within the range tested—it lies between about 3.5 and 3.7Ω/.

It has been found that, using the same type of multilayer coating but using metallic Ti blocker layer instead of the interface layer, as in the case of counterexample 5, and by varying the thickness of the metallic Ti blocker layer over the same thickness range, a variation of a few ohms is observed from one end of the range to the other.

### Underblocker Film 30 and Overblocker Film 50

FIG. 3 illustrates an embodiment of the invention corresponding to a multilayer coating that includes a single functional layer 40, the functional layer 40 of which is provided with an underblocker film 30 and with an overblocker film 50.

It has been found that the effects obtained for the multilayer coatings of examples 2, 3 on the one hand and 12 and 13 on the other were accumulative and that the resistivity of the multilayer coating was further improved.

To improve the mechanical resistance, the multilayer coating is covered with a protective layer 200 based on a mixed oxide, such as a mixed tin zinc oxide.

Examples comprising several functional layers were also produced. They result in the same conclusions as previously.

FIG. 5 thus illustrates an embodiment having two silver-based functional metallic layers 40, 80 and three dielectric films 20, 60, 100, said films being composed of a plurality of layers, 22, 24; 62, 64, 66; 102, 104 respectively, so that each functional layer is placed between at least two dielectric films:
the silver-based layers 40, 80 are deposited using a silver target, under a pressure of 0.8 Pa in a pure argon atmosphere;
the layers 24; 62, 66; 102 are based on ZnO and deposited by reactive sputtering using a zinc target, under a pressure of 0.3 Pa and in an argon/oxygen atmosphere; and
the layers 22, 64 and 104 are based on Si₃N₄ and deposited by reactive sputtering using an aluminum-doped silicon target, under a pressure of 0.8 Pa in an argon/nitrogen atmosphere.

The multilayer coating is covered with a protective layer 200 based on a mixed oxide, such as a mixed tin zinc oxide.

Each functional layer 40, 80 is deposited on an underblocker film 30, 70 consisting, respectively, of an interface layer 32, 72 made of titanium oxide TiOₓ immediately in contact with said functional layer.

FIG. 6 also shows an embodiment, this time with four silver-based functional metallic layers 40, 80, 120, 160 and five dielectric films 20, 60, 100, 140, 180, said films being composed of a plurality of layers, 22, 24; 62, 64, 66; 102, 104, 106; 142, 144, 146; 182, 184, respectively so that each functional layer is placed between at least two dielectric films:
the silver-based layers 40, 80, 120, 160 are deposited using a silver target, under a pressure of 0.8 Pa in a pure argon atmosphere;
the layers 24; 62, 66; 102, 106; 142, 146; 182 are based on ZnO and deposited by reactive sputtering using a zinc target, under a pressure of 0.3 Pa and in an argon/oxygen atmosphere; and
the layers 22, 64, 104, 144 and 184 are based on Si₃N₄ and deposited by reactive sputtering using a boron-doped or aluminum-doped silicon target, under a pressure of 0.8 Pa in an argon/nitrogen atmosphere.

The multilayer coating is also covered with a protective layer 200 based on a mixed oxide, such as a mixed tin zinc oxide.

Each functional layer 40, 80, 120, 160 is deposited on an underblocker film 30, 70, 110, 150 consisting, respectively, of an interface layer 32, 72, 112, 152 made of titanium oxide TiOₓ immediately in contact with said functional layer.

The present invention has been described above by way of example. It should be understood that a person skilled in the art is capable of producing various alternative embodiments of the invention without thereby departing from the scope of the patent as defined by the claims.

1. A substrate (10), especially a transparent glass substrate, provided with a thin-film multilayer coating comprising an alternation of n functional layers (40) having reflection properties in the infrared and/or in solar radiation, especially metallic functional layers based on silver or on a metal alloy containing silver, and (n+1) dielectric films (20, 60), where n≧1, said films being composed of a layer or a plurality of layers (22, 24, 62, 64), including at least one made of a dielectric material, so that each functional layer (40) is placed between at least two dielectric films (20, 60), characterized in that at least one functional layer (40) includes a blocker film (30, 50) consisting of at least one interface layer (32, 52) immediately in contact with said functional layer, this interface layer being based on titanium oxide TiOₓ.

2. The substrate (10) as claimed in claim 1, characterized in that the multilayer coating comprises two functional layers (40, 80) alternating with three films (20, 60, 100).

3. The substrate (10) as claimed in claim 1 or claim 2, characterized in that the interface layer (32, 52) made of TiOₓ is partially oxidized where 1.5≦x≦1.98.

4. The substrate (10) as claimed in any one of the preceding claims, characterized in that the interface layer (32, 52) has a geometric thickness of less than 5 nm and preferably between 0.5 and 2 nm.

5. The substrate (10) as claimed in any one of the preceding claims, characterized in that the interface layer (32, 52) includes one or more other chemical elements chosen from at least one of the following materials Ti, V, Mn, Co, Cu, Zn, Zr, Hf, Al, Nb, Ni, Cr, Mo, Ta, or from an alloy based on at least one of these materials.

6. The substrate (10) as claimed in any one of the preceding claims, characterized in that the interface layer (32, 52) is deposited using a ceramic target, in a nonoxidizing atmosphere.

7. The substrate (10) as claimed in any one of the preceding claims, characterized in that the blocker film (30, 50) further includes one or more other layers.

8. The substrate (10) as claimed in any one of the preceding claims, characterized in that the blocker film (30, 50) has a geometric thickness of between 0.5 and 5 nm, even between 1 and 10 nm if it comprises at least two layers.

9. Glazing incorporating at least one substrate (10) as claimed in any of the preceding claims, optionally combined with at least one other substrate.

10. The glazing as claimed in the preceding claim, mounted as monolithic glazing or as multiple glazing of the double-glazing type or laminated glazing, characterized in that at least the substrate bearing the multilayer coating is made of curved or toughened glass.

11. A process for manufacturing the substrate (10) as claimed in any one of claims 1 to 8, characterized in that the thin-film multilayer coating is deposited on the substrate (10) by a vacuum technique of sputtering, possibly magnetron sputtering type, and in that the interface layer (32, 52) is deposited using a ceramic target in a nonoxidizing atmosphere.
